(19) United States
(12) Patent Application Publication
(10) Pub. No.: US 2026/0247582 A1
(43) Pub. Date: Aug. 20, 2026

(54) LIQUID COOLING SYSTEM MANAGEMENT USING A MANAGEMENT CONTROLLER

(71) Applicant: American Megatrends International, LLC, Duluth, GA (US)

(72) Inventors: Varadachari Sudan Ayanam, Suwanee, GA (US); Chitrak Gupta, Johns Creek, GA (US); Sanay Ahuja, Suwanee, GA (US); Venkatesan Balakrishnan, Chennai (IN)

(21) Appl. No.: 19/055,632

(22) Filed: Feb. 18, 2025

(51) Int. Cl. H05K 7/20

(52) U.S. Cl. CPC H05K 7/20836; H05K 7/20236; H05K 7/20772

(57) ABSTRACT

One or more computing devices receive cooling system data from a cooling distribution unit (CDU) using a legacy management protocol. The one or more computing devices convert the cooling system data from the legacy management protocol to a standardized management protocol. The one or more computing devices transmit the converted cooling system data to a data center manager using the standardized management protocol.

### BACKGROUND

### Field

The present disclosure relates generally to computer systems, and more particularly, to techniques of managing liquid cooling systems in data centers using a management controller that provides protocol translation between legacy cooling system protocols and standardized management protocols while enabling secure out-of-band management capabilities.

### BACKGROUND

The statements in this section merely provide background information related to the present disclosure and may not constitute prior art.

Data centers have traditionally relied on air-based cooling systems using fans to manage the thermal requirements of servers and computing equipment. However, with the increasing prevalence of AI workloads and high-performance computing, these traditional air cooling methods have become insufficient to handle the intense heat generation from modern processors and GPUs. This has led to the emergence of liquid cooling solutions, which offer superior thermal management capabilities compared to air-based systems.

Two main approaches to liquid cooling have been developed: direct-to-chip cooling using cold plates, and full immersion cooling. In direct-to-chip cooling, cold liquid is circulated through plates attached directly to CPUs and GPUs, while still requiring supplementary air cooling for other components. Immersion cooling takes a more comprehensive approach by submerging entire server systems in dielectric cooling liquid, allowing for more efficient heat transfer across all components. Both methods utilize Cooling Distribution Units (CDUs) to circulate and manage the cooling liquid, with the CDUs incorporating various sensors to monitor temperature, flow rates, and liquid levels.

These liquid cooling systems have relied on legacy protocols such as Modbus and SNMP (Simple Network Management Protocol) for system management and monitoring. Each cooling system vendor typically implements their own proprietary management interface on top of these protocols, leading to fragmentation in management approaches. These legacy protocols also present significant limitations they lack modern security features, do not support standardized management frameworks like Redfish, and cannot provide comprehensive out-of-band management capabilities that are crucial for large-scale data center operations. Additionally, the traditional implementations often don't allow for consolidated monitoring and control across multiple cooling units, making it challenging to manage cooling infrastructure at scale.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect of the disclosure, a method, a computer-readable medium, and a system are provided. The system may include one or more computing devices. The one or more computing devices receive cooling system data from a cooling distribution unit (CDU) using a legacy management protocol. The one or more computing devices convert the cooling system data from the legacy management protocol to a standardized management protocol. The one or more computing devices transmit the converted cooling system data to a data center manager using the standardized management protocol.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 is a diagram illustrating a computer system having a baseboard management controller (BMC) and a host computer.

FIG. 2 is a diagram illustrating a liquid cooling system architecture having a cooling distribution unit (CDU) and a liquid tank that communicate using legacy management protocols.

FIG. 3 is a diagram illustrating an improved liquid cooling system architecture incorporating a management controller that translates between legacy protocols and standardized management protocols.

FIG. 4 is a flow chart illustrating a method for managing liquid cooling systems through protocol translation and data conversion.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of computer systems will now be presented with reference to various apparatus and methods. These apparatus and methods will be described in the following detailed description and illustrated in the accompanying drawings by various blocks, components, circuits, processes, algorithms, etc. (collectively referred to as elements). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a processing system that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

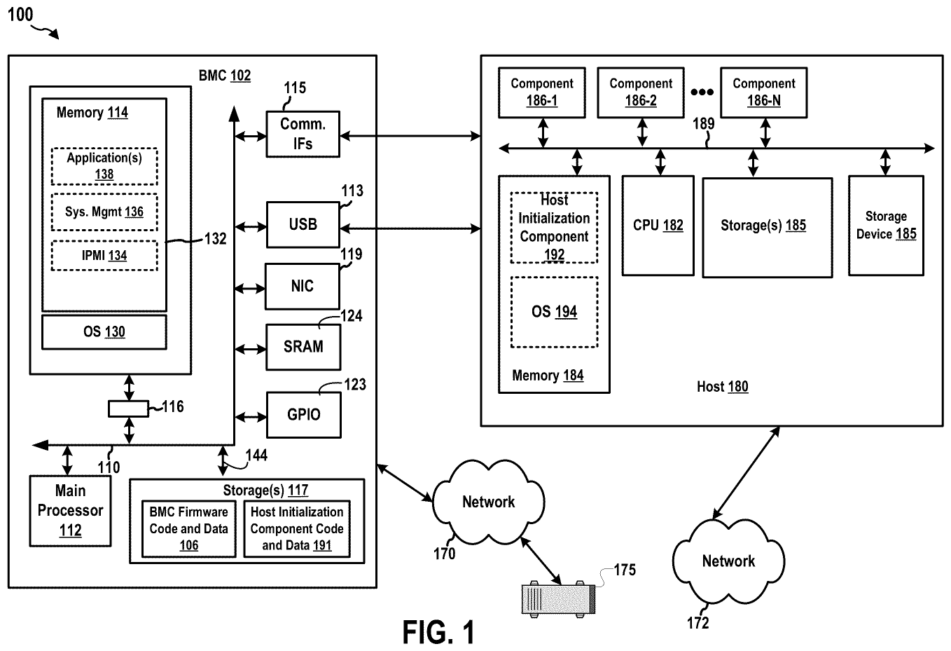

FIG. 1 is a diagram illustrating a computer system 100. In this example, the computer system includes, among other devices, a baseboard management controller (BMC) 102 and a host computer 180. The BMC 102 has, among other components, a main processor 112, a memory 114 (e.g., a dynamic random access memory (DRAM)), a memory driver 116, storage(s) 117, a network interface card 119, a USB interface 113 (i.e., Universal Serial Bus), other communication interfaces 115, a SRAM 124 (i.e., static RAM), and a GPIO interface 123 (i.e., general purpose input/output interface).

The communication interfaces 115 may include a keyboard controller style (KCS), a server management interface chip (SMIC), a block transfer (BT) interface, a system management bus system interface (SSIF), and/or other suitable communication interface(s). Further, as described infra, the BMC 102 supports IPMI and provides an IPMI interface between the BMC 102 and the host computer 180. The IPMI interface may be implemented over one or more of the USB interface 113, the network interface card 119, and the communication interfaces 115.

In certain configurations, one or more of the above components may be implemented as a system-on-a-chip (SoC). For examples, the main processor 112, the memory 114, the memory driver 116, the storage(s) 117, the network interface card 119, the USB interface 113, and/or the communication interfaces 115 may be on the same chip. In addition, the memory 114, the main processor 112, the memory driver 116, the storage(s) 117, the communication interfaces 115, and/or the network interface card 119 may be in communication with each other through a communication channel 110 such as a bus architecture.

The BMC 102 may store BMC firmware code and data 106 in the storage(s) 117. The storage(s) 117 may utilize one or more non-volatile, non-transitory storage media. During a boot-up, the main processor 112 loads the BMC firmware code and data 106 into the memory 114. In particular, the BMC firmware code and data 106 can provide in the memory 114 an BMC OS 130 (i.e., operating system) and service components 132. The service components 132 include, among other components, IPMI services 134, a system management component 136, and application(s) 138. Further, the service components 132 may be implemented as a service stack. As such, the BMC firmware code and data 106 can provide an embedded system to the BMC 102.

The BMC 102 may be in communication with the host computer 180 through the USB interface 113, the network interface card 119, the communication interfaces 115, and/or the IPMI interface, etc.

The host computer 180 includes a host CPU 182, a host memory 184, storage device(s) 185, and component devices 186-1 to 186-N. The component devices 186-1 to 186-N can be any suitable type of hardware components that are installed on the host computer 180, including additional CPUs, memories, and storage devices. As a further example, the component devices 186-1 to 186-N can also include Peripheral Component Interconnect Express (PCIe) devices, a redundant array of independent disks (RAID) controller, and/or a network controller.

Further, the storage(s) 117 may store host initialization component code and data 191 for the host computer 180. After the host computer 180 is powered on, the host CPU 182 loads the initialization component code and data 191 from the storage(s) 117 though the communication interfaces 115 and the communication channel 110. The host initialization component code and data 191 contains an initialization component 192. The host CPU 182 executes the initialization component 192. In one example, the initialization component 192 is a basic input/output system (BIOS). In another example, the initialization component 192 implements a Unified Extensible Firmware Interface (UEFI). UEFI is defined in, for example, “Unified Extensible Firmware Interface Specification Version 2.6, dated January, 2016,” which is expressly incorporated by reference herein in their entirety. As such, the initialization component 192 may include one or more UEFI boot services.

The initialization component 192, among other things, performs hardware initialization during the booting process (power-on startup). For example, when the initialization component 192 is a BIOS, the initialization component 192 can perform a Power On System Test, or Power On Self Test, (POST). The POST is used to initialize the standard system components, such as system timers, system DMA (Direct Memory Access) controllers, system memory controllers, system I/O devices and video hardware (which are part of the component devices 186-1 to 186-N). As part of its initialization routine, the POST sets the default values for a table of interrupt vectors. These default values point to standard interrupt handlers in the memory 114 or a ROM. The POST also performs a reliability test to check that the system hardware, such as the memory and system timers, is functioning correctly. After system initialization and diagnostics, the POST surveys the system for firmware located on non-volatile memory on optional hardware cards (adapters) in the system. This is performed by scanning a specific address space for memory having a given signature. If the signature is found, the initialization component 192 then initializes the device on which it is located. When the initialization component 192 includes UEFI boot services, the initialization component 192 may also perform procedures similar to POST.

After the hardware initialization is performed, the initialization component 192 can read a bootstrap loader from a predetermined location from a boot device of the storage device(s) 185, usually a hard disk of the storage device(s) 185, into the host memory 184, and passes control to the bootstrap loader. The bootstrap loader then loads an OS 194 into the host memory 184. If the OS 194 is properly loaded into memory, the bootstrap loader passes control to it. Subsequently, the OS 194 initializes and operates. Further, on certain disk-less, or media-less, workstations, the adapter firmware located on a network interface card re-routes the pointers used to bootstrap the operating system to download the operating system from an attached network.

The service components 132 of the BMC 102 may manage the host computer 180 and is responsible for managing and monitoring the server vitals such as temperature and voltage levels. The service stack can also facilitate administrators to remotely access and manage the host computer 180. In particular, the BMC 102, via the IPMI services 134, may manage the host computer 180 in accordance with IPMI. The service components 132 may receive and send IPMI messages to the host computer 180 through the IPMI interface.

Further, the host computer 180 may be connected to a data network 172. In one example, the host computer 180 may be a computer system in a data center. Through the data network 172, the host computer 180 may exchange data with other computer systems in the data center or exchange data with machines on the Internet.

The BMC 102 may be in communication with a communication network 170 (e.g., a local area network (LAN)). In this example, the BMC 102 may be in communication with the communication network 170 through the network interface card 119. Further, the communication network 170 may be isolated from the data network 172 and may be out-of-band to the data network 172 and out-of-band to the host computer 180. In particular, communications of the BMC 102 through the communication network 170 do not pass through the OS 194 of the host computer 180. In certain configurations, the communication network 170 may not be connected to the Internet. In certain configurations, the communication network 170 may be in communication with the data network 172 and/or the Internet. In addition, through the communication network 170, a remote device 175 may communicate with the BMC 102. For example, the remote device 175 may send IPMI messages to the BMC 102 over the communication network 170.

Further, the storage(s) 117 is in communication with the communication channel 110 through a communication link 144.

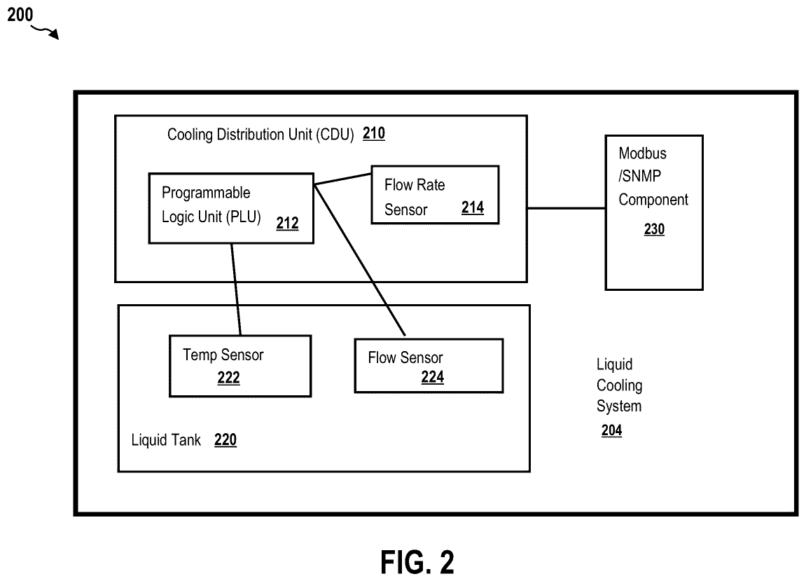

FIG. 2 is a diagram 200 illustrating a liquid cooling system architecture according to a first scheme. In this first scheme, a liquid cooling system 204 includes a Cooling Distribution Unit (CDU) 210 and a liquid tank 220 that work together to provide cooling capabilities.

The CDU 210 includes a Programmable Logic Unit (PLU) 212 that controls the cooling operations and a flow rate sensor 214 that monitors the flow of cooling liquid. The PLU 212 serves as the main control unit for managing the cooling functions within the CDU 210. The flow rate sensor 214 provides flow rate measurements to determine the liquid circulation through the system.

The liquid tank 220 contains multiple sensing components for monitoring the cooling environment. A temperature sensor 222 measures the temperature of the cooling liquid, while a flow sensor 224 monitors the liquid flow within the tank. These sensors communicate their measurements to the PLU 212 through direct connections as shown by the blue lines in the diagram.

A Modbus/SNMP component 230 provides the legacy management interface capabilities for the system. This component enables external communication and control using traditional protocols like Modbus and SNMP (Simple Network Management Protocol). The component 230 connects to the CDU 210 to receive operational data and send control commands according to these legacy protocols.

In this first scheme, the management architecture relies on these legacy protocols, which presents limitations in modern data center environments. The direct communication between components using proprietary implementations makes it challenging to integrate with contemporary management frameworks. Additionally, the traditional protocol-based approach lacks standardized management capabilities and does not support comprehensive out-of-band management features that are increasingly important in modern data center operations where consolidated thermal and power management at scale is required.

The liquid cooling system 204 represents an advancement over traditional air-cooled systems, particularly for high-powered AI and compute workloads that generate significant heat. However, the management interface limitations of this first scheme create obstacles for efficient system administration and monitoring in large-scale deployments.

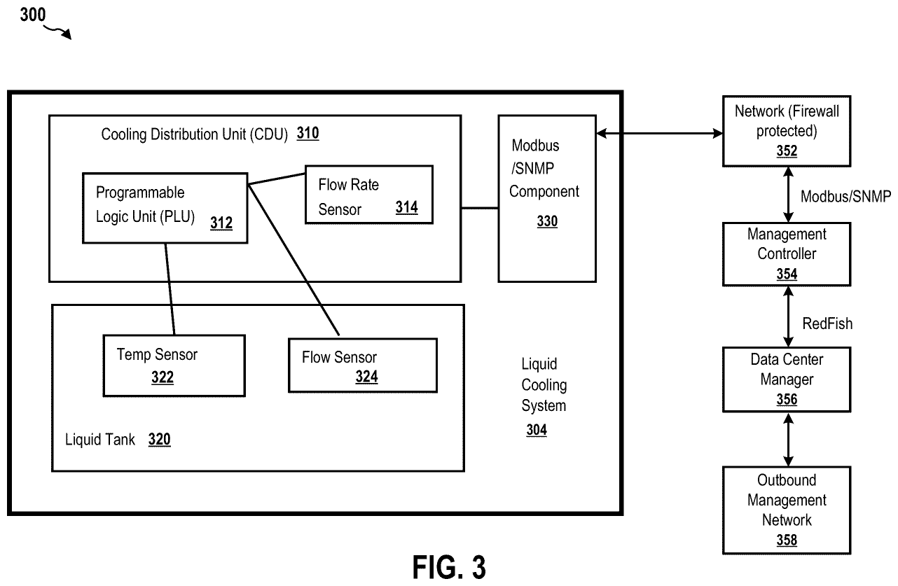

FIG. 3 is a diagram 300 illustrating a liquid cooling system architecture according to a second scheme. The second scheme builds upon and improves the first scheme by introducing additional management and security capabilities.

In this second scheme, the liquid cooling system 304 incorporates similar core components as the first scheme, including the Cooling Distribution Unit (CDU) 310 with its Programmable Logic Unit (PLU) 312 and flow rate sensor 314. The liquid tank 320 maintains the same essential monitoring capabilities through its temperature sensor 322 and flow sensor 324. The Modbus/SNMP component 330 continues to provide the base communication protocol support.

The significant advancement in the second scheme comes from the introduction of a network 352 that connects to a management controller 354. This network 352 is firewall-protected, creating a secure boundary between the legacy protocols and modern management interfaces. The management controller 354 serves as a protocol translation layer, converting the legacy Modbus and SNMP communications from the CDU 310 into standardized RedFish protocol data. This translated data flows to a data center manager 356, which can then distribute it through an outbound management network 358.

More specifically, the liquid cooling systems in the first scheme, as depicted in FIG. 2, rely on legacy management interfaces such as Modbus and SNMP for communication between the CDU 210 and external management systems. These protocols present several limitations in modern data center environments, particularly concerning scalability, security, and integration with contemporary management standards like RedFish. Each liquid cooling system vendor often has proprietary implementations, making it challenging to achieve consistent management across different systems.

In the second scheme, the management controller 354 serves as an abstraction layer between the legacy protocols used by the CDU 310 and a standardized management interface for external systems. The management controller 354 is a specialized hardware component designed to enhance the manageability and security of liquid cooling systems in data center environments. This controller can be implemented as a standalone device, integrated into an aggregated switch, or as a separate appliance equipped with a microcontroller. The management controller 354 acts as an intermediary between the liquid cooling system 304 and the data center manager 356, providing protocol translation, data aggregation, and security enforcement.

The primary function of the management controller 354 is to convert legacy protocols, such as Modbus and SNMP, used by the cooling distribution unit (CDU) 310 into the standardized RedFish protocol. This conversion allows for seamless integration with modern data center management systems. The management controller 354 receives data from the CDU 310 via the Modbus/SNMP component 330, which is connected to the firewall-protected network 352. The received data includes sensor readings from the temperature sensor 322, the flow sensor 324, and the flow rate sensor 314, as well as operational status and diagnostic information from the programmable logic unit (PLU) 312.

The management controller 354 parses the incoming Modbus or SNMP data streams and maps the information to corresponding RedFish data structures. This mapping involves translating proprietary data formats and non-standard parameters into a uniform representation defined by the RedFish specification. For example, temperature readings from the temperature sensor 322 are converted into RedFish temperature sensor objects, and flow rate measurements from the flow rate sensor 314 are represented as RedFish flow sensor objects.

Modern data centers often contain a heterogeneous mix of CDUs that communicate through various protocols. Some CDUs utilize Modbus, others employ SNMP, and newer models may implement RedFish, though with inconsistent data modeling approaches.

The management controller 354 in the second scheme functions as a protocol abstraction layer, capable of interfacing with multiple communication protocols simultaneously. When receiving data from a CDU 310, the management controller 354 first identifies the specific protocol being used by that unit. This protocol detection enables the management controller 354 to properly interpret incoming data streams, whether they originate from older CDUs using Modbus or newer units implementing different protocols.

The management controller can normalize these diverse protocol implementations into a standardized RedFish data model. The management controller 354 maintains protocol mapping tables that define the relationships between various vendor-specific implementations and the standardized RedFish schema. For example, when receiving temperature data from the temperature sensor 322 through a Modbus interface, the management controller 354 translates the proprietary data format into the corresponding RedFish thermal sensor model.

The protocol handling capabilities of the management controller 354 extend beyond simple protocol translation. The controller implements a discovery mechanism to automatically detect and identify the communication protocols supported by each connected CDU. This discovery process enables the management controller 354 to establish appropriate communication channels with each CDU, regardless of its protocol implementation. The discovered protocol information is stored within the management controller 354 and used to maintain persistent connections with multiple CDUs simultaneously.

Through the firewall-protected network 352, the management controller 354 aggregates data from multiple CDUs that may be using different protocols. This aggregated data is then normalized and presented to the data center manager 356.

As such, legacy CDUs using Modbus or SNMP protocols can be integrated into modern management frameworks without requiring modifications to their existing firmware or communication interfaces. This compatibility is particularly valuable in data centers that operate a mix of older and newer cooling infrastructure, as it allows for unified management across generations of cooling equipment.

In addition to protocol translation, the management controller 354 aggregates data from multiple CDUs. In large data center deployments, a single management controller 354 can connect to and manage several CDUs, collecting data from each and consolidating it into a unified view. This aggregated data is then transmitted to the data center manager 356 using the RedFish protocol over the outbound management network 358. The data center manager 356, in turn, utilizes this information for monitoring, analysis, and control of the entire data center cooling infrastructure.

The management controller 354 also provides bidirectional communication capabilities. It not only translates data from the liquid cooling system 304 to the data center manager 356 but also relays commands from the data center manager 356 back to the CDU 310. This allows for remote control and adjustment of the cooling system's parameters. For instance, the data center manager 356 can send a command to adjust the flow rate based on real-time temperature readings. The management controller 354 receives this command in RedFish format, converts it into the appropriate Modbus or SNMP command, and forwards it to the CDU 310 through the Modbus/SNMP component 330.

Further, the management controller 354 may enforce role-based access control and policy-based management for all write operations and control commands directed to the CDU 310. While read operations, such as retrieving sensor data, are permitted without restriction, any command that modifies the cooling system's operation undergoes rigorous security validation. The management controller 354 checks the user's credentials and permissions against predefined policies to determine whether the requested action is authorized. This prevents unauthorized access and potential misconfigurations that could compromise the cooling system's performance or damage the servers being cooled.

More specifically, the management controller 354 may implement a comprehensive security interface layer that differentiates between read and write operations. In one example, while read operations for monitoring sensor data from the temperature sensor 322, flow sensor 324, and flow rate sensor 314 are permitted with basic authentication, write operations that modify CDU 310 parameters undergo rigorous security validation. The management controller 354 enforces role-based access control policies for all modification requests received through the outbound management network 358.

When the data center manager 356 sends a control command, such as adjusting cooling parameters, the management controller 354 first validates the request against predefined security policies. These policies can specify which roles have authorization to modify specific CDU parameters, establishing a hierarchical access control system. For example, certain administrative roles may have permission to modify flow rate thresholds, while others may only have permission to view operational data. The management controller 354 can maintain detailed audit logs of all modification attempts, successful or otherwise, enabling security monitoring and compliance tracking.

The management controller 354 can be implemented either as a standalone appliance with a dedicated microcontroller or integrated into an aggregated switch or a BMC.

The firewall-protected network 352 isolates the Modbus/SNMP component 330 and the connected CDUs from direct external access. This isolation mitigates the security risks associated with legacy protocols, which often lack robust security features. By placing the Modbus/SNMP communication behind a firewall and using the management controller 354 as a secure gateway, the second scheme maintains compatibility with existing cooling infrastructure while incorporating modern security standards.

The management controller 354 can be implemented using various hardware platforms. One option is to utilize a standard baseboard management controller (BMC), such as the BMC 102 described in FIG. 1. The BMC 102, with its main processor 112, memory 114, and various communication interfaces, can be programmed to perform the protocol translation, data aggregation, and security functions required of the management controller 354. Alternatively, a customized BMC or a dedicated microcontroller-based appliance can be used to implement the management controller 354.

A key architectural feature of this second scheme is its scalability. Though the diagram shows a one-to-one relationship, a single management controller 354 can interface with multiple CDUs, aggregating their data and providing centralized management through the data center manager 356. This aggregation capability becomes particularly valuable in large data center deployments where numerous liquid cooling systems must be monitored and managed efficiently.

The management controller 354 in the second scheme introduces out-of-band management capability that is not available in the first scheme. In the first scheme, as depicted in FIG. 2, the Modbus/SNMP component 230 typically provides a management interface that is in-band, meaning it shares the same network path as the data traffic. This configuration can lead to management traffic being blocked or deprioritized during periods of high network congestion. Furthermore, in-band management can pose security risks if the data network is compromised. In contrast, the second scheme, as depicted in FIG. 3, uses the management controller 354 to provide out-of-band management. The management controller 354 is connected to the data center manager 356. This separation allows management traffic to flow even when the in-band data network is unavailable or compromised. The out-of-band management capability provided by the management controller 354 allows administrators to remotely access, monitor, and control the liquid cooling system 304 independently of the host computer's 180 operating system 194 and network stack.

The management controller 354 facilitates advanced monitoring and control capabilities that are not present in the first scheme. The management controller 354 receives real-time data from multiple sensors within the liquid cooling system 304, including the temperature sensor 322, the flow sensor 324, and the flow rate sensor 314. This data is transmitted to the data center manager 356, which processes the information to provide a comprehensive view of the cooling system's performance. The data center manager 356 can analyze the sensor data to detect anomalies, predict potential issues, and optimize the cooling process. For example, if the data center manager 356 detects a sudden increase in temperature from the temperature sensor 322, it can trigger an alert to notify administrators of a potential cooling problem. Similarly, if the flow rate sensor 314 indicates a decrease in liquid flow, the data center manager 356 can adjust the flow rate through the management controller 354 to maintain optimal cooling performance.

The management controller 354 also supports bidirectional communication, allowing the data center manager 356 to send commands back to the CDU 310. This capability enables administrators to remotely control the cooling system and make adjustments as needed. For instance, if the data center manager 356 determines that the flow rate needs to be adjusted based on the data from the flow sensor 324, it can send a command to the management controller 354 to modify the flow rate. The management controller 354 receives the command in RedFish format, converts it into the appropriate Modbus or SNMP command, and forwards it to the CDU 310 via the Modbus/SNMP component 330. The PLU 312 in the CDU 310 then executes the command to adjust the flow rate accordingly. This bidirectional communication allows for dynamic control of the cooling system, enabling administrators to respond quickly to changing conditions and maintain optimal performance.

In addition to flow rate adjustments, the management controller 354 can also relay other types of commands from the data center manager 356 to the CDU 310. For example, the data center manager 356 can send commands to adjust temperature thresholds, activate or deactivate cooling units, or modify other operational parameters. The management controller 354 ensures that these commands are properly formatted and securely transmitted to the CDU 310. The PLU 312 in the CDU 310 receives the commands and implements the requested changes, providing a closed-loop control system that allows for precise management of the liquid cooling system 304. This level of control is particularly important in large data center environments where maintaining optimal cooling efficiency is essential for reliable operation and energy conservation.

One use case that illustrates the benefits of the management controller 354 involves the detection and resolution of flow sensor issues. Suppose the data center manager 356 receives data from the flow sensor 324 indicating an irregular flow pattern. The data center manager 356 can analyze this data and determine that the flow sensor 324 may need adjustment or recalibration. The data center manager 356 can then send a command to the management controller 354 to adjust the flow sensor 324 settings. The management controller 354 converts this command into the appropriate Modbus or SNMP format and transmits it to the CDU 310. The PLU 312 receives the command and adjusts the flow sensor 324 accordingly. This adjustment can resolve the irregular flow pattern and restore optimal cooling performance. Additionally, the management controller 354 can provide feedback to the data center manager 356 confirming that the adjustment has been made, ensuring that administrators are aware of the changes and can monitor the system's performance.

Another use case involves the detection of leaks within the liquid cooling system 304. The liquid tank 320 may include leak sensors that can detect the presence of liquid outside of the designated cooling pathways. If a leak is detected, the leak sensor sends an alert to the PLU 312, which relays the information to the management controller 354 via the Modbus/SNMP component 330. The management controller 354 then transmits the alert to the data center manager 356. The data center manager 356 can notify administrators of the leak and provide detailed information about its location and severity. The data center manager 356 can also send commands to the management controller 354 to isolate the affected area or shut down the cooling system to prevent further damage. The management controller 354 relays these commands to the CDU 310, which takes appropriate action to mitigate the leak. This rapid response capability helps to minimize downtime and protect the server hardware from potential damage caused by liquid exposure.

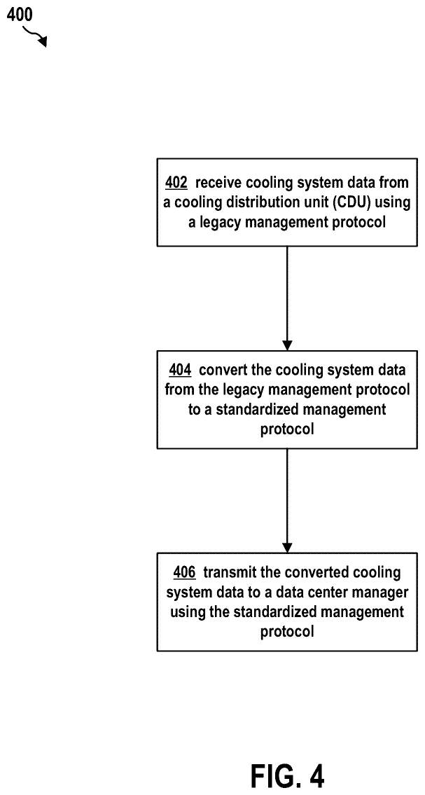

FIG. 4 is a flow chart 400 of a method for managing liquid cooling systems. The method may be performed by one or more computing devices (e.g., the management controller 354). In operation 402, the one or more computing devices receive cooling system data from a cooling distribution unit (CDU) using a legacy management protocol. In operation 404, the one or more computing devices convert the cooling system data from the legacy management protocol to a standardized management protocol. In operation 406, the one or more computing devices transmit the converted cooling system data to a data center manager using the standardized management protocol.

In certain configurations, the legacy management protocol comprises at least one of Modbus or Simple Network Management Protocol (SNMP), and the standardized management protocol comprises RedFish. The one or more computing devices receive sensor data from a plurality of sensors associated with the CDU, the plurality of sensors comprising at least one of a temperature sensor, a flow sensor, or a flow rate sensor. The one or more computing devices aggregate the sensor data with the cooling system data prior to the converting. The one or more computing devices receive a control command from the data center manager using the standardized management protocol, convert the control command from the standardized management protocol to the legacy management protocol, and transmit the converted control command to the CDU.

To validate control commands, the one or more computing devices determine whether the control command comprises a write operation. When the control command comprises the write operation, the one or more computing devices validate authorization for the write operation based on security policies and transmit the converted control command to the CDU only upon successful validation of the authorization. To validate the authorization, the one or more computing devices perform role-based access control verification for the write operation and log the write operation in an audit log.

In certain configurations, the one or more computing devices receive cooling system data from multiple CDUs using different legacy management protocols, identify, for each CDU, a corresponding legacy management protocol being used, convert the cooling system data from each CDU based on its corresponding legacy management protocol, and aggregate the converted cooling system data from the multiple CDUs before transmitting to the data center manager. To receive the cooling system data, the one or more computing devices receive the cooling system data through a firewall-protected network that isolates the CDU from direct external access.

In certain configurations, the one or more computing devices monitor real-time sensor data from the CDU, detect an anomaly in the sensor data, generate an alert based on the detected anomaly, and transmit the alert to the data center manager using the standardized management protocol. To detect the anomaly, the one or more computing devices detect at least one of an irregular flow pattern, a temperature threshold violation, or a liquid leak condition. To transmit the converted cooling system data, the one or more computing devices transmit the converted cooling system data through an out-of-band management network that is separate from a data network used by servers being cooled by the CDU.

In certain configurations, the one or more computing devices discover protocol capabilities of the CDU during initialization and store protocol mapping information for the discovered protocol capabilities. To convert the cooling system data, the one or more computing devices map proprietary data formats from the legacy management protocol to standardized data structures defined by the standardized management protocol.

In certain configurations, the one or more computing devices comprise a baseboard management controller (BMC) or a dedicated microcontroller-based appliance, and the CDU is configured to cool one or more servers through liquid immersion cooling. The one or more computing devices receive operational parameters from the CDU, analyze the operational parameters to determine cooling optimization adjustments, and transmit control commands to implement the cooling optimization adjustments to the CDU through the legacy management protocol.

The liquid cooling system architectures shown in FIGS. 2-3 may be implemented to cool the host computer 180 shown in FIG. 1. Specifically, the host computer 180, which includes the host CPU 182, host memory 184, storage device(s) 185, and component devices 186-1 to 186-N, may be cooled through immersion cooling by being fully immersed in the liquid tank 220/320 containing non-conductive dielectric cooling liquid. The CDU 210/310 circulates and manages the cooling liquid through the liquid tank to remove heat generated by the components of the host computer 180.

Furthermore, the management controller 354 shown in FIG. 3 may be implemented using the BMC 102 architecture detailed in FIG. 1. The BMC 102, with its main processor 112, memory 114, network interface card 119, and other communication interfaces 115, can be programmed to perform the protocol translation between legacy Modbus/SNMP protocols and RedFish, as well as handle the security policies, data aggregation, and out-of-band management functions required by the management controller 354. The BMC 102's network interface card 119 can connect to both the firewall-protected network 352 to communicate with the CDU 310 and to a communication link to communicate with the data center manager 356

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A method, implemented by one or more computing devices, comprising:
receiving, by a management controller, cooling system data from a cooling distribution unit (CDU) using a legacy management protocol;
converting, by the management controller, the cooling system data from the legacy management protocol to a standardized management protocol; and
transmitting the converted cooling system data to a data center manager using the standardized management protocol.

2. The method of claim 1, wherein:
the legacy management protocol comprises at least one of Modbus or Simple Network Management Protocol (SNMP); and
the standardized management protocol comprises RedFish.

3. The method of claim 1, further comprising:
receiving sensor data from a plurality of sensors associated with the CDU, the plurality of sensors comprising at least one of a temperature sensor, a flow sensor, or a flow rate sensor; and
aggregating the sensor data with the cooling system data prior to the converting.

4. The method of claim 1, further comprising:
receiving, by the management controller, a control command from the data center manager using the standardized management protocol;
converting the control command from the standardized management protocol to the legacy management protocol; and
transmitting the converted control command to the CDU.

5. The method of claim 4, further comprising:
determining whether the control command comprises a write operation;
validating, when the control command comprises the write operation, authorization for the write operation based on security policies; and
transmitting the converted control command to the CDU only upon successful validation of the authorization.

6. The method of claim 5, wherein validating the authorization comprises at least one of:
performing role-based access control verification for the write operation; and
logging the write operation in an audit log.

7. The method of claim 1, further comprising:
receiving cooling system data from multiple CDUs using different legacy management protocols;
identifying, for each CDU, a corresponding legacy management protocol being used;
converting the cooling system data from each CDU based on its corresponding legacy management protocol; and
aggregating the converted cooling system data from the multiple CDUs before transmitting to the data center manager.

8. The method of claim 1, wherein receiving the cooling system data comprises:
receiving the cooling system data through a firewall-protected network that isolates the CDU from direct external access.

9. The method of claim 1, further comprising:
monitoring real-time sensor data from the CDU;
detecting an anomaly in the sensor data;
generating an alert based on the detected anomaly; and
transmitting the alert to the data center manager using the standardized management protocol.

10. The method of claim 9, wherein detecting the anomaly comprises:
detecting at least one of an irregular flow pattern, a temperature threshold violation, or a liquid leak condition.

11. The method of claim 1, wherein transmitting the converted cooling system data comprises:
transmitting the converted cooling system data through an out-of-band management network that is separate from a data network used by servers being cooled by the CDU.

12. The method of claim 1, further comprising:
discovering, by the management controller, protocol capabilities of the CDU during initialization; and
storing protocol mapping information for the discovered protocol capabilities.

13. The method of claim 1, wherein converting the cooling system data comprises:
mapping proprietary data formats from the legacy management protocol to standardized data structures defined by the standardized management protocol.

14. The method of claim 1, wherein:
the management controller comprises a baseboard management controller (BMC) or a dedicated microcontroller-based appliance; and
the CDU is configured to cool one or more servers through liquid immersion cooling.

15. The method of claim 1, further comprising:
receiving operational parameters from the CDU;
analyzing the operational parameters to determine cooling optimization adjustments; and
transmitting control commands to implement the cooling optimization adjustments to the CDU through the legacy management protocol.

16. A system, including one or more computing devices, comprising:
a memory; and
at least one processor coupled to the memory and configured to:
receive cooling system data from a cooling distribution unit (CDU) using a legacy management protocol;
convert the cooling system data from the legacy management protocol to a standardized management protocol; and
transmit the converted cooling system data to a data center manager using the standardized management protocol.

17. The system of claim 16, wherein:
the legacy management protocol comprises at least one of Modbus or Simple Network Management Protocol (SNMP); and
the standardized management protocol comprises RedFish.

18. The system of claim 16, wherein the at least one processor is further configured to:
receive sensor data from a plurality of sensors associated with the CDU, the plurality of sensors comprising at least one of a temperature sensor, a flow sensor, or a flow rate sensor; and
aggregate the sensor data with the cooling system data prior to the converting.

19. The system of claim 16, wherein the at least one processor is further configured to:
receive a control command from the data center manager using the standardized management protocol;
convert the control command from the standardized management protocol to the legacy management protocol; and
transmit the converted control command to the CDU.

20. A non-transitory computer-readable medium storing computer executable code for operating one or more computing devices, comprising code to:
receive, by a management controller, cooling system data from a cooling distribution unit (CDU) using a legacy management protocol;
convert, by the management controller, the cooling system data from the legacy management protocol to a standardized management protocol; and
transmit the converted cooling system data to a data center manager using the standardized management protocol.
